(19) United States
(12) Patent Application Publication
(10) Pub. No.: US 2014/0187289 A1
(43) Pub. Date: Jul. 3, 2014

(54) Modular Components and Methods for an Electronic Device

(71) Applicants: John Cataldo, Westlake Village, CA (US); Daniel C. Sullivan, Santa Barbara, CA (US); Mardis Bagley, San Francisco, CA (US)

(72) Inventors: John Cataldo, Westlake Village, CA (US); Daniel C. Sullivan, Santa Barbara, CA (US); Mardis Bagley, San Francisco, CA (US)

(73) Assignee: HEADLOGIC LLC, Westlake Village, CA (US)

(21) Appl. No.: 13/733,574

(22) Filed: Jan. 3, 2013

(51) Int. Cl. H05K 7/14; H05K 13/00; H04M 1/02

(52) U.S. Cl. CPC H05K 7/14; H04M 1/0202; H05K 13/00
USPC 455/557; 361/679.01; 29/825

(57) ABSTRACT

A kit of parts and method for using the same with an electronic computing device includes providing a case for an electronic device, the case has a receiver plate attachable to a peripheral device, encasing the electronic device with the case to protect the electronic device and to enable the electronic device to physically connect to a peripheral device, selecting a peripheral device from a group of peripheral devices, attaching the selected peripheral device to the receiver plate to stow the peripheral device in proximity with the electronic device, and thereby assure that the selected peripheral device is readily available for use, detaching the selected peripheral device from the receiver plate to enable optimal placement of the selected peripheral device in proximity to the electronic device, and establishing wireless electronic communication between the electronic device and the selected peripheral device.

### RELATED APPLICATIONS

This patent application relates in subject matter to commonly assigned U.S. patent application Ser. No. 13/621,332, filed 17 Sep. 2012, the disclosure of which is incorporated herein by reference.

### FIELD OF THE INVENTION

The present invention relates to cases for electronic devices, particularly, computing devices having cases that connect to a variety of peripheral hardware.

### BACKGROUND OF THE INVENTION

Smart phones have become the standard for cellular phone companies in many countries. Sales of simple phones, having minimal computing power and non-touch screen interfaces, are diminishing in favor of smart phones having touch screens and various applications that can be downloaded and operated via the smart phone.

Cases for smart phones are found on many, if not most, smart phones that are in use. Cases protect the phones from the elements, and protect the smart phone against impact. Many cases are both stylish and utilitarian.

Smart phones have gained broad acceptance in the marketplace and many desire peripherals to further bolster the smart phone capacities, and this is made possible because of technological advancements in battery life, computing power and memory storage.

Examples of useful peripheral components include retractable ear-bud mechanisms, secondary battery packs, video projectors, supplemental display screens, speaker systems, microphones, printers, and other specialized components such as heart rate monitors, pedometers, health monitoring devices, and scientific measurement devices.

One drawback of such peripheral devices is that if they are not co-located in proximity with the phone, they are difficult to use. Those users owning many peripheral devices may easily misplace one or more of these devices, rendering them useless until found. Ways of organizing peripheral devices so that they can stay with a smart phone are desired.

### SUMMARY OF THE INVENTION

The present invention devises a way of organizing peripheral devices in proximity with an electronic device, such as a smart phone so that the peripheral device is optimally stored in proximity with the electronic device. This is accomplished by providing a case that has a modular physical connection capability, which allows a physical attachment of the case to any of a variety of peripheral devices. In this way those that may be inclined to misplace a peripheral device will have a way of storing the peripheral device with the electronic device i.e. smart phone.

The invention includes a kit of parts for an electronic device having a case for an electronic device. The case has a receiver plate attachable to a peripheral device. The kit of parts includes a peripheral device attachable to the receiver plate and being capable of electronic communication with the electronic device. Electronic communication includes digital and analog signals, as well as DC current.

The receiver plate is rigid and defines recesses that are configured to hold a peripheral device. The peripheral device includes a number of feet that are able to align with the recesses to enable the peripheral device to attach to the receiver plate of the case.

The peripheral device is selected from the group consisting of, a retractable ear-bud mechanism, a speaker, a solar battery charger, a video projector, a flexible video display screen. It is envisioned that spare batteries, sound microphones, printers, and other specialized components such as heart rate monitors, pedometers, health testing devices, and scientific measurement devices are included in the scope of the present invention.

In one embodiment, the receiver plate includes four recesses arranged in a rectangular configuration. The peripheral device includes four feet that align with the four recesses of the receiver plate when the peripheral device attaches to the receiver plate. The receiver plate attaches to the case in one embodiment, and the receiver plate is integrated into the case in another embodiment.

In addition to a friction fit between the recesses of the receiver plate and the feet of the peripheral device, the receiver plate may include supplement retainers to hold the peripheral device. In one embodiment, magnets attached to the receiver plate, the magnets and the recesses cooperate to retain the peripheral device on the receiver plate. In a variation of this embodiment, one magnet attaches to the plate adjacent each recess.

In one embodiment, the electronic device is a smart phone and the peripheral device is a speaker having a Bluetooth™ interface capable of communicating with the smart phone.

In another embodiment, the peripheral device is a video projector having a wireless interface capable of networked communication with the smart phone.

In a further embodiment, the peripheral device is a solar battery charger for charging the smart phone, or the speaker. The solar battery charger being capable of wired electronic communication with the smart phone and with the speaker, the solar battery charger folds for stowage and attachment to the electronic device, and unfolds for capturing light to charge the electronic device.

In another embodiment, the electronic device is a smart phone and the peripheral device is a display screen. The screen is flexible and rolls from a stowed configuration where the screen is sized for attachment to the electronic device, and an operational configuration where the screen unrolls. The display screen preferably is a roll-up or folding OLED screen.

The roll-up screen has two ends, and roller tube at each of the two ends that selectively dispense and retract the screen. The roller tube is equipped with feet to enable the retainer plate to hold the screen when the screen is in the stowed configuration.

### BRIEF DESCRIPTION OF THE DRAWINGS

FIG. 1 shows a perspective view of a case for an electronic device having a cartridge for managing ear bud cables attached thereto.

FIG. 2 shows an exploded perspective view of the case of FIG. 1 with an optional speaker attaching thereto.

FIG. 3 shows a bottom exploded perspective view of the case and speaker of FIG. 2.

FIG. 4 shows an top view of an embodiment of a speaker on the case.

FIG. 5 shows a rear perspective view of the speaker of FIG. 4 attached to the case.

FIG. 6 shows a rear perspective view of a video projector attached to a case.

FIG. 7a show a perspective view of a clip stand for attachment to a peripheral device in accordance with the present invention.

FIG. 7b shows a sectional view of the clip stand of FIG. 7a as seen along the line b-b of FIG. 7a.

FIG. 8a shows a perspective view of a speaker attached to the clip stand of FIGS. 7a-d.

FIG. 8b shows a side view of the speaker and clip stand of FIG. 8a.

FIG. 9 shows an exploded perspective view of a video projector attached to the clip stand of FIGS. 7a-7d.

FIG. 10a shows a perspective view of the case of FIG. 1 electronically connected to a foldable solar charger pad, and a clip stand.

FIG. 10b shows a perspective view of the case of FIG. 1 attached to the solar charging pad of FIG. 10a, which is folded.

FIG. 11a is an exploded perspective view of the case of FIG. 1 attached to a flexible display screen in a stow-able configuration.

FIG. 11b is a perspective view of the case and screen of FIG. 11a with the display screen unrolled into an operational configuration.

FIG. 12 is a flow chart of a method in accordance with the present invention.

### DETAILED DESCRIPTION

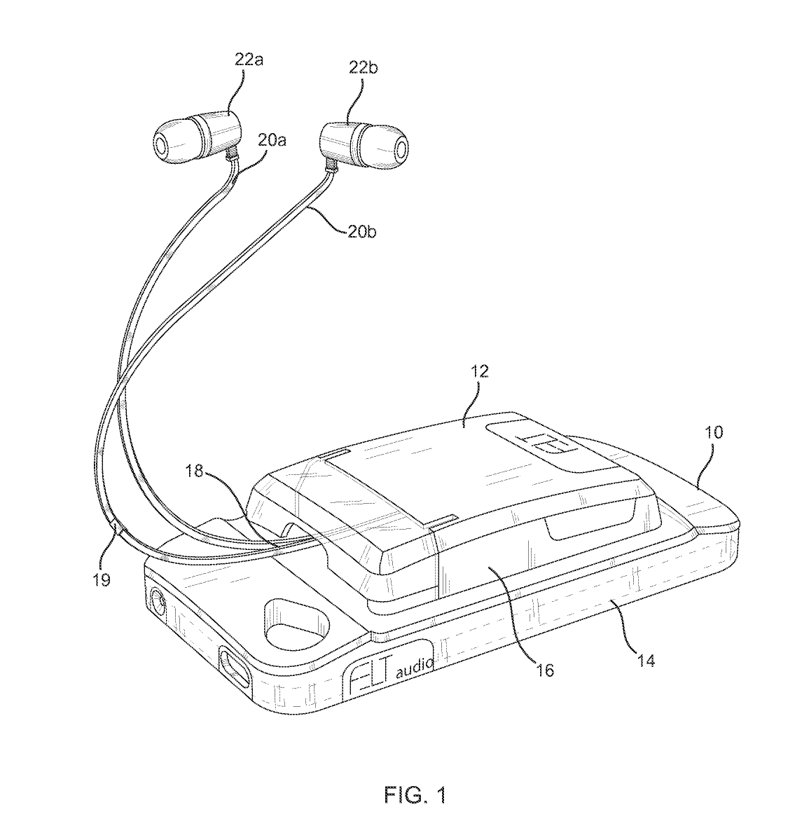

FIG. 1 shows a case 10 in accordance with the present invention and a peripheral device. Here the peripheral device is a retractable ear bud module 12.

The ear bud module 12 removeably attaches to the case 10. The case 10 holds electronic device 14 (shown with hidden lines) having an audio output capability, video output capability, data output capability, or any combination thereof The electronic device 14 is preferably a smart phone, music player, a tablet computer, or other computing device.

Output capability is defined as output to an interface integrated into the electronic device such as a screen and speaker, or output to a wireless network, or other wired or wireless output to at least one peripheral device, or both.

In a preferred embodiment, the electronic device 14 is enabled with wireless audio output capability, for example a Bluetooth™ communication module having a radio and a processor, where the radio transmits and receives audio signals via a host-less Bluetooth™ communication protocol such as defined by the trade organization, Bluetooth SIG, and other trade organizations. In another embodiment, the electronic device 14 is equipped with a wireless networking hardware in accordance with 802.11x protocols, or functionally similar networking protocol currently used, or contemplated for future development.

The ear bud module 12 removeably attaches to the case 10. This removable attachment can include a clipped attachment that includes a press-fit between the ear bud module 12 and the case 10. In an alternate embodiment of the invention the ear bud module 12 slidably connects to the case 10. The use of a user actuated switch supplements the press-fit and slideable connection between the ear bud module 12 and the case 10 to enable a locking connection between the case 10 and the ear bud module 12.

The ear bud module 12 includes a housing 16 and an ear bud cable 18, which retractably holds an ear bud cable 18. The ear bud cable 18 has free ends 20a and 20b and ear buds 22a and 22b attached to the free ends 20a and 20b, respectively.

In one embodiment, the ear bud cable 18 is equipped with a microphone 19 to enable telephonic communication between the microphone 19 and the electronic device 14 (shown in hidden line view) via a wireless connection.

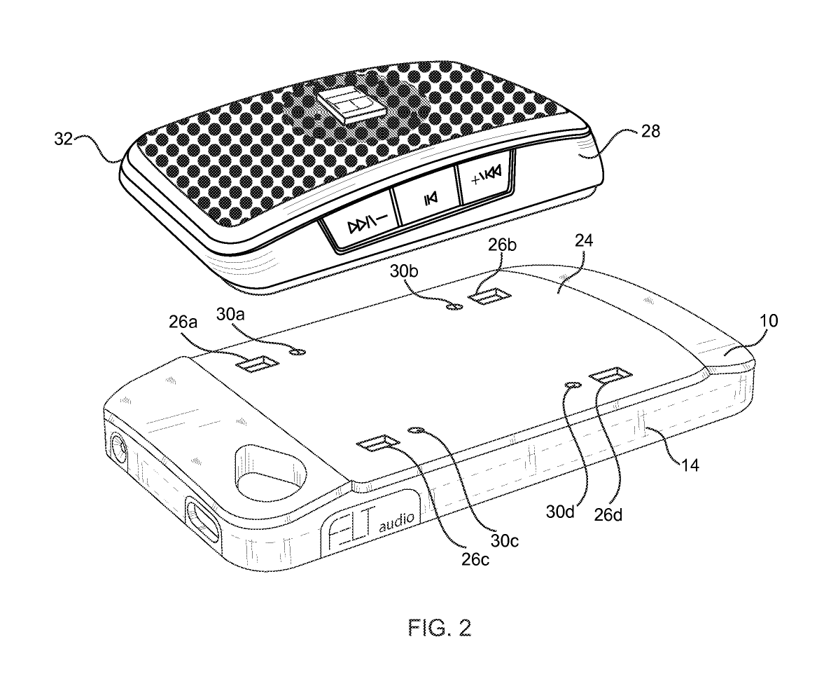

FIG. 2 shows a case 10 for holding an electronic device 14. The case includes a receiver plate 24. The receiver plate 24 is rigid and defines four recesses 26a, 26b, 26c, and 26d to enable the peripheral device 32 to attach to the receiver plate 24.

The peripheral device 32 is a sound speaker 28 in this example, however the peripheral devices disclosed and suggested herein each are configured for attachment to the receiver plate 24 in the same manner as the sound speaker 28 to enable the case 10 to achieve modular attachment of a variety of peripheral device 32 to the electronic device 14 via the case 10.

The sound speaker 28, or other peripheral device, physically connects to the case 24 to enable optimal placement of the speaker 28 in proximity to the electronic device 14. Optimal placement reduces the chance that the speaker will become separated from the phone and lost.

The receiver plate 24 includes magnets 30a, 30b, 30c, and 30d. The magnets 30a, 30b, 30c, and 30d attach to the receiver plate 24 adjacent the recesses 26a, 26b, 26c, and 26d, respectively to guide the speaker 28 in alignment with the recesses 26a, 26b, 26c, and 26d, and to cooperate with these recesses to hold the speaker 28.

Optimally the peripheral device 32, e.g. the speaker 28 drops onto the receiver plate 24 over the recesses and slides to lock the peripheral device in the recesses. The magnets online the peripheral device with the receiver plate 24 when the peripheral device slides on the receiver plate 24.

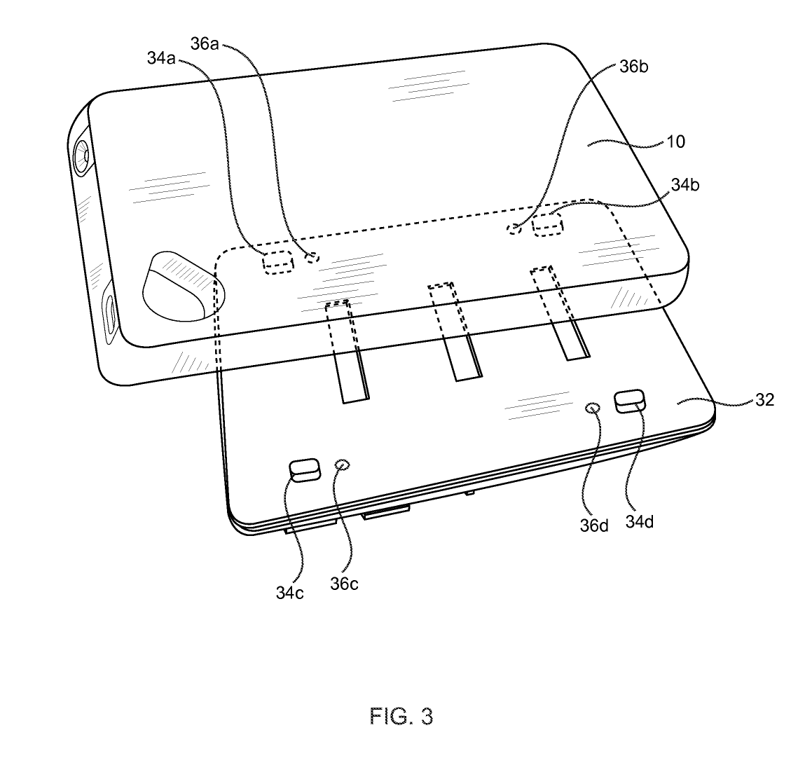

FIG. 3 shows a bottom perspective view of a peripheral device 32 and the case 10. The peripheral device 32 includes four feet 34a, 34b, 34c, and 34d, which align with, and lock with, the recesses 26a, 26b, 26c and 26d, respectively of FIG. 2. The peripheral device 32 includes four magnets 36a, 36b, 36c, and 36d, which align with, and lock with, the respective magnets 30a, 30b, 30c, and 30d shown in FIG. 2. In an alternate embodiment, the case 10 includes ferrous plates instead of magnets.

The peripheral device 32 can include any one or more of the following: a retractable ear-bud mechanism, a speaker, a solar battery charger, a video projector, or a flexible video display screen. It is envisioned that spare batteries, sound microphones, printers, and other specialized components such as heart rate monitors, pedometers, health testing devices, and scientific measurement devices are included in the scope of peripheral devices 32 contemplated to be within the scope of the present invention.

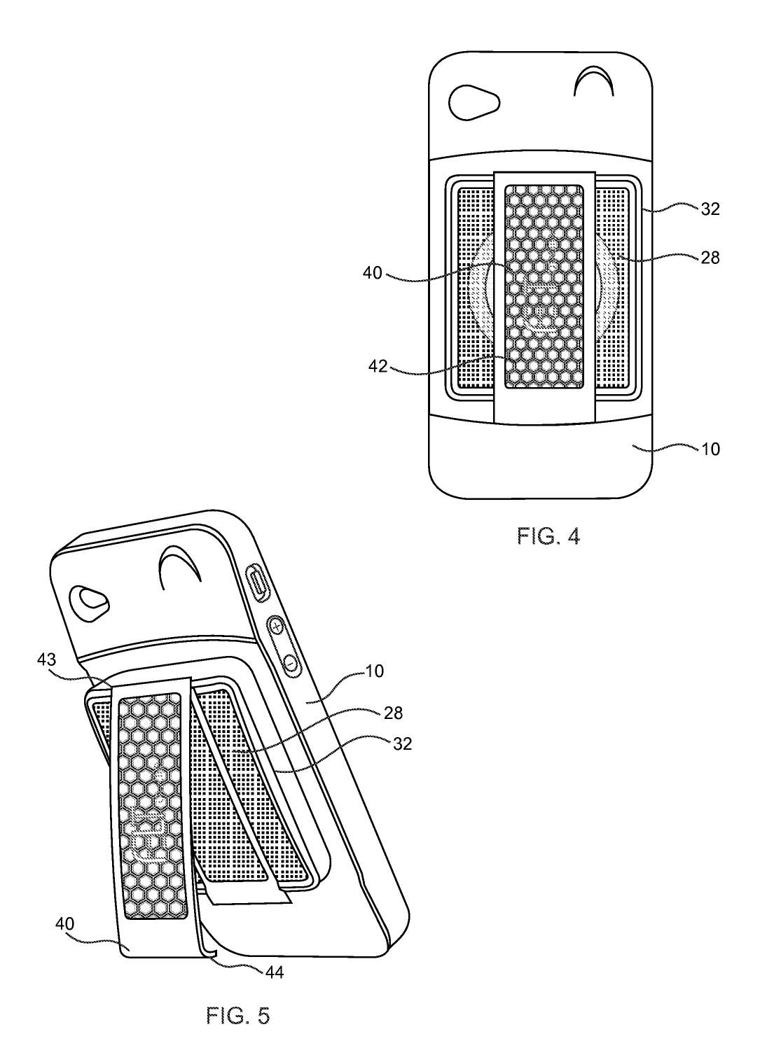

FIG. 4 shows a top view of a peripheral device 32 attached to the case 10. The peripheral device 32 includes a speaker 28 and a stand 40. The stand 40 attaches directly to the speaker 32. The stand 40 includes multiple acoustic openings 42 that enable sound to pass through the stand 40 during operation of the speaker 32.

FIG. 5 shows a rear perspective view of the peripheral device 32 of FIG. 4 attached to the case 10. The stand 40 is integral with the speaker 28 has a first end with a hinge 43 and the second end with a curved foot 44. The stand hinges open to enable the foot 44 to support the case 10 in an operational configuration. The stand 40 folds flush with the speaker 28 during stowage and use when the speaker 28 attaches to the case 10 and the foot 44 is not needed.

Accordingly the peripheral device 32 has multiple functions. The first function is to provide supplemental sound to an electronic device inside the case 10 and the second is to provide a standing mechanism to support the case 10 and an operational configuration.

The speaker 28 is detachable from the case 10 and establishes electronic communication with an electronic device held by the case 10. Preferably the electronic communication between the speaker 28 and the electronic device is wireless and complies with current, or to be developed, Bluetooth™ connectivity protocols.

In an alternate embodiment, the speaker 28 connects to the electronic device held within the case 10 via contemporary networking protocols such as 802.11x utilizing a hub, router or other networking hardware.

It can be appreciated that although a speaker 28 is shown by example the wireless protocols suggested above can also be applied to any peripheral device 32 contemplated by the present invention.

FIG. 6 shows a peripheral device 32 attached to the case 10. The peripheral device 32 includes a video projector 46 having legs 48a and 48b. The video projector 46 includes feet and attaches to the retainer plate of the case 10 as shown in FIG. 3.

The video projector 46 encloses a battery connected to video processing circuitry and has a projector lens 50 located at one and of the video projector 46. The legs 48a and 48b of the video projector 46 each have a first length 52 that attaches to a lateral side of the video projector 32 and the second length 54a and 54b, respectively, that folds out from a respective lateral side of the video projector 32 to stand the video projector 46 and the case 10 and an orientation which enables use of the video projector 32.

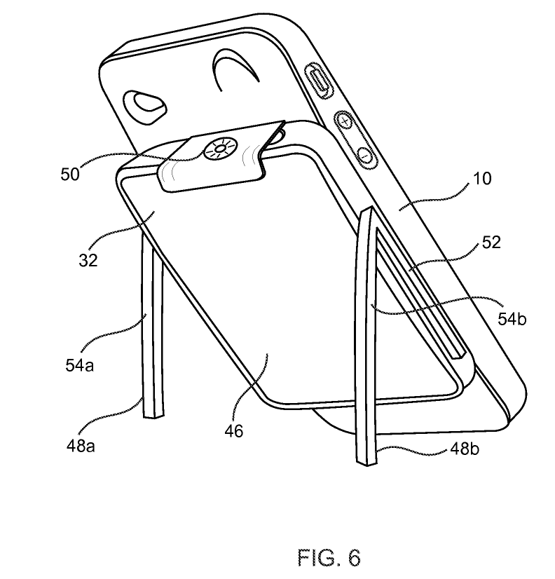

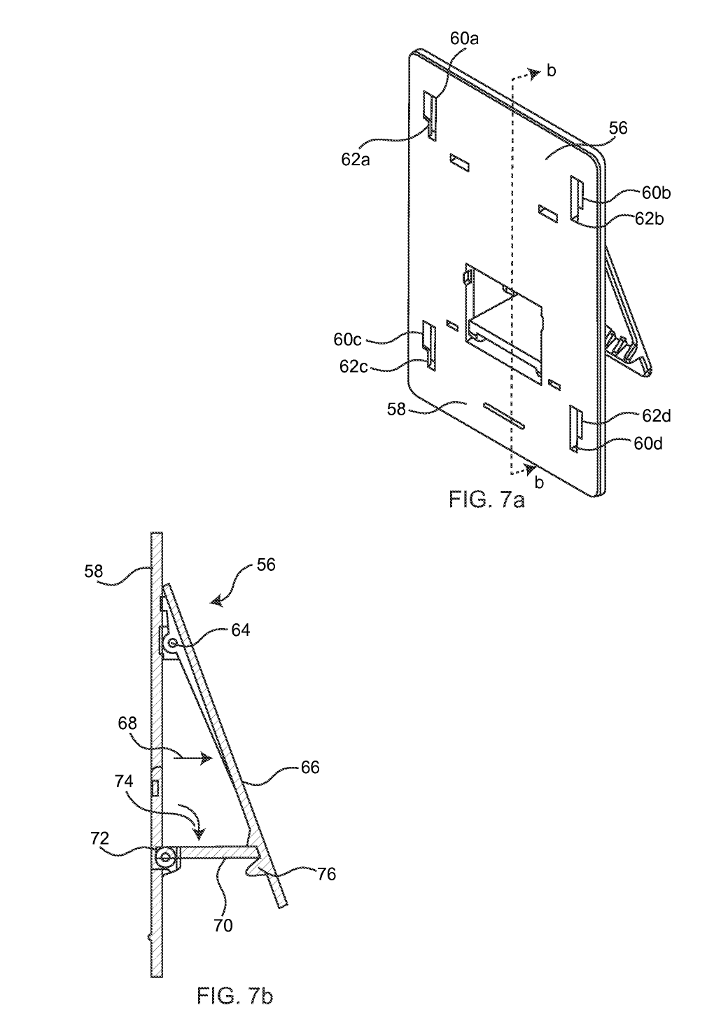

FIG. 7a shows a perspective view of a clip stand 56 having a retainer plate 58 that when provided as part of a kit of parts, duplicates the receiver plate 24 of the case 10.

In one embodiment, the retainer plate 58 is rectangular and includes for recesses 60a, 60b, 60c, and 60d positioned near corners of the retainer plate 58. Each recess 60a, 60b, 60c, and 60d and shaped having an elongated rectangle adjacent a shorter rectangle where the shorter rectangle abuts retaining lip 62a, 62b, 62c or 62d. The shorter and larger rectangles are intended to receive the feet of a peripheral device pressed perpendicularly toward the retainer plate 58. The lips 62a, 62b, 62c and 62d enable peripheral device feet formed with a slot to then slide into a press fit arrangement with the retainer plate 58. It can be appreciated that the retainer plate 24 of FIG. 2 can also be configured with an elongated rectangle and the shorter rectangle to similarly receive the formed with a slot.

FIG. 7b shows a sectional side view of the clip stand 56 of FIG. 7A as seen along the line b-b of FIG. 7A. The clip stand 56 includes a retainer plate 58, a hinge 64, a clip member 66 attached to a rear portion of the retainer plate 58 by the hinge 64. The hinge 64 enables the clip member 66 to open from the rear portion of the retainer plate 58 in the direction of the arrow 68.

The clip stand 56 also includes a folding lock 70 and a lock hinge 72. The lock hinge 72 is spring loaded to normally retain the folding lock 70 flush against the rear portion of the retainer plate 58. The lock hinge 72 enables the folding lock 72 open in the direction of the arrow 74 two lock the clip member 66 an open configuration to form a stand. The clip member also includes a detent 76 to hold and lock the folding lock 70 when the folding lock 70 and the clip member 66 are both in an open configuration.

The clip stand 56 functions to offer belt-clip functionality when the folding lock 70 lies flush with the retainer plate 58, where the belt-clip can also attach to other articles of clothing, or on a bag, or visor of a car, for examples. Alternatively, the clip stand 56 functions to offer tabletop stand when the folding lock is in the open configuration. In the kit of parts of the present invention therefore, the peripheral device can be attached to either a case for an electronic device or to a clip stand, which functions as a belt clip or a table stand.

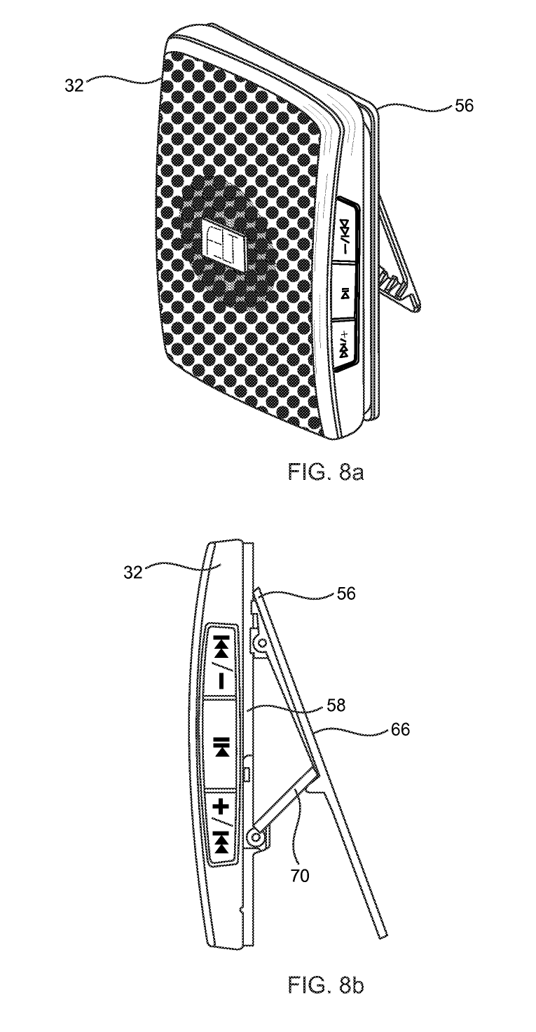

FIG. 8a shows a perspective view of the clip stand 56 with a speaker 32 attached. The clip stand 56 offers tabletop stand functionality. The tabletop stand functionality can be used on any flat surface and may be adapted to conform to uneven or sloped surfaces.

FIG. 8b shows the clip stand 56 and speaker 32 and a side view having the folding lock 70 and the clip member 66 an open configuration. The clip stand 56 is intended as an accessory to the kit of parts of the present invention which enables a peripheral device to attach to the retainer plate 58 of the clip stand 56. The clip stand 56 is an alternative to the physical connection to the case 10 of FIG. 1.

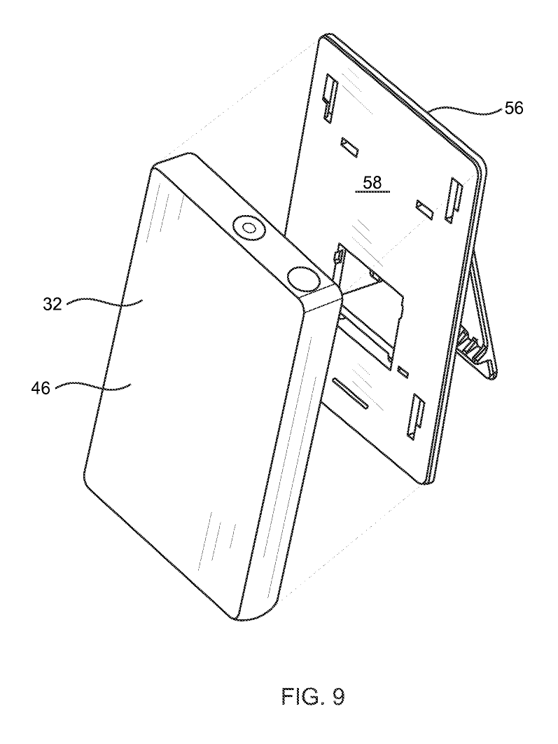

FIG. 9 shows a clip stand 56 exploded from the peripheral device 32, which attaches to the retainer plate 58 of the clip stand 56. As shown the peripheral device 32 is a video projector 46, however it can be appreciated that any peripheral device 32 can attached to the retainer plate 58 of the clip stand 56. It can also be appreciated that the retainer plate 58 can be duplicated and integrated into the case 10 to enable the peripheral device 32 two attached either to the clip stand 56 or to the case 10. The benefit of duplicating and integrating the retainer plate 58 on a clip stand 56 and on a case 10 enables the modular components, e.g. peripheral devices 32 to selectively attach to either a case or the clip stand 56.

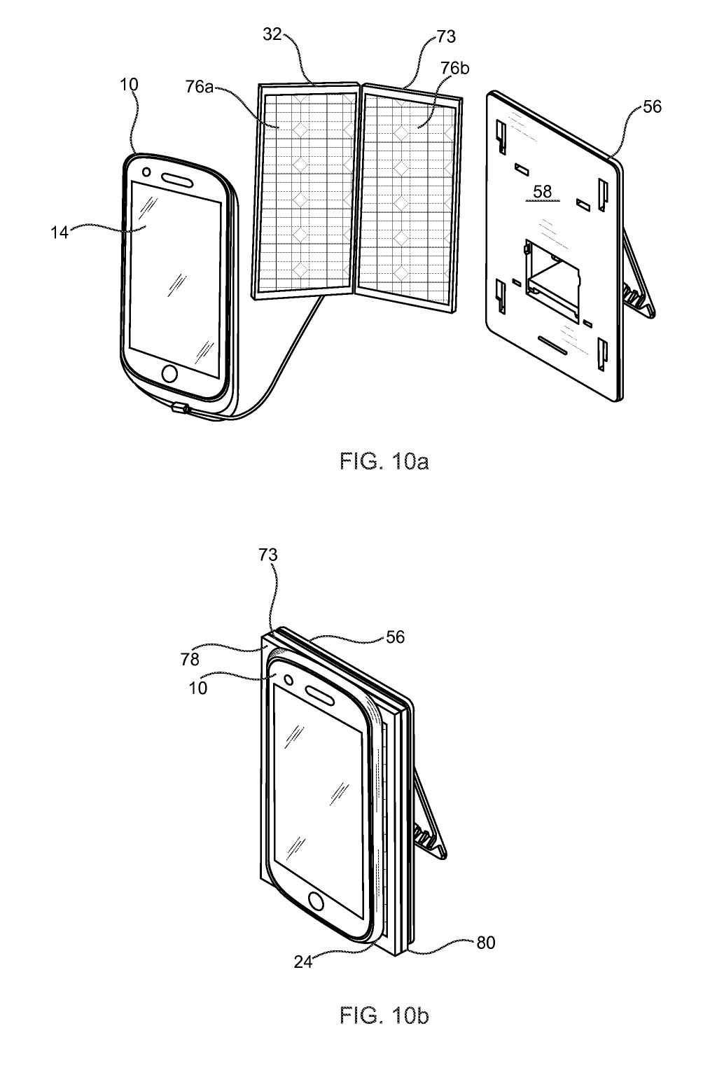

FIG. 10a shows the case 10 and the electronic device 14 with a wired connection to a peripheral device 32, which includes a solar charger 73. The wired connection enables electronic communication between the solar charger 73 and the electronic device 14. The solar charger 73 is foldable to conform and size to the case 10 and also to the retainer plate 58 of the clip stand 56. In an open configuration solar charger 73 enables light to recharge batteries in the electronic device 14. In a closed configuration, the solar charger 73 has a face equipped with two photo voltaic surfaces 76a and 76b, and a rear portion that attaches to the case 10 for convenient carrying an optimal stowage for later use. In the closed configuration, the photo voltaic surfaces 76a and 76b face each other. The solar charger 73 has a second rear portion that attaches to the clip stand 56. Accordingly a peripheral device 32 such as the solar charger 73 is capable of attachment to both the case 10 and to the clip stand 56, either alternatively, or simultaneously.

FIG. 10b shows the solar charger 73 attached to the case 10. The solar charger 73 is in a closed configuration. A first rear portion 78 attaches to the receiver plate 24 of the case 10. A second rear portion 80 of the solar charger 73 attaches to the receiver plate 58 (shown in FIG. 10a) of the clip stand 56.

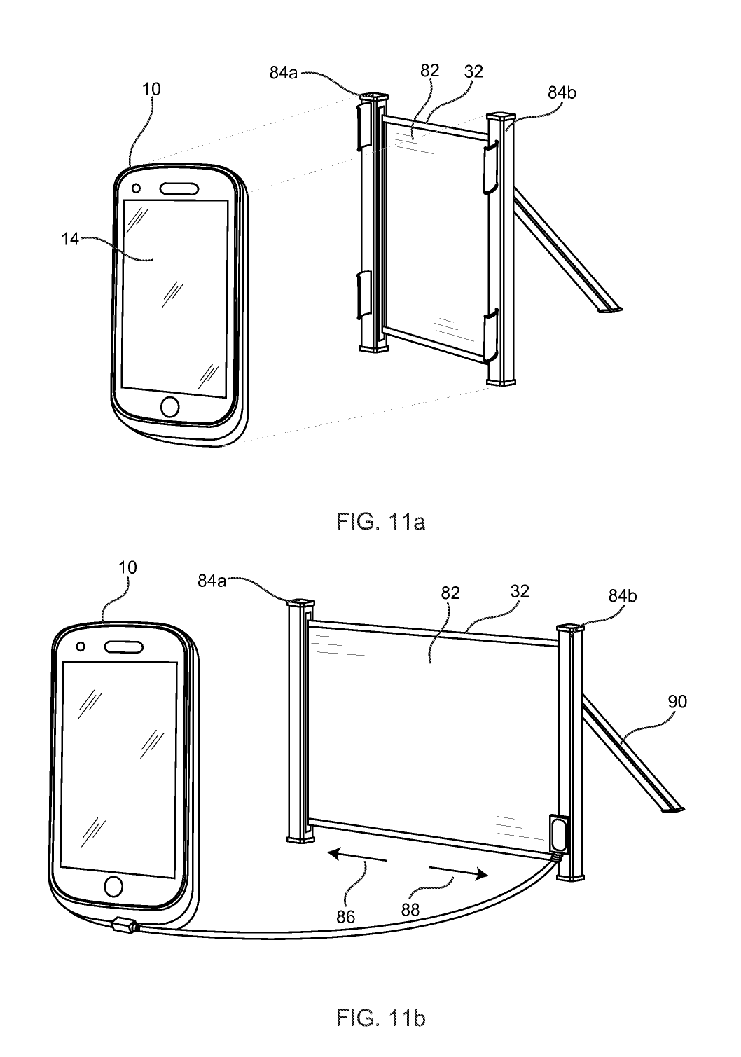

FIG. 11a shows a case 10 holding an electronic device 14. The electronic device is a smart phone. Exploded from the case is a peripheral device 32 including a display screen 82. The display screen 82 is flexible and roles from a stowed configuration as shown where the screen 82 is sized for attachment to the case 10 and electronic device 14, to an operational configuration where the screen 82 unrolls. Preferably the screen is a rollup OLED film having two ends. Each end includes a roller tube 84a and 84b, respectively.

The roller tubes 84a and 84b each receive and retain a portion of the display screen 82 when the display screen 82 is in the stowed configuration as shown. However, it can be appreciated that it is feasible to utilize a single roller tube in accordance with the present invention. It can also be appreciated that the rollup OLED screen 82 can be folded and a configuration similar to the example of the solar charger 73 and FIGS. 10a and 10b.

FIG. 11b shows the display screen 82 of FIG. 11a in an operational configuration as the roller tubes 84a and 84b move apart in the direction of the arrows 86 and 88 to reveal a larger viewing surface than what would be visible in the stowed configuration of FIG. 11a. In this embodiment of folding leg 90 attaches to at least one of the roller tubes 84a or 84b, to support the display screen 82.

FIG. 12 shows a method in accordance with the present invention. A method is for using kit of parts for an electronic device. The method includes the step 92 of providing a case for an electronic device, the step 94 of encasing the electronic device in the case, the step 96 of selecting a peripheral device from a group of peripheral devices and attaching the selected peripheral device to the case, the step 98 of detaching the peripheral device from the case, the step 100 of establishing electronic communication between the electronic device and the peripheral device, and the step 102 of detaching the peripheral device from the case.

The case has a receiver plate attachable to a peripheral device. The step 94 of encasing the electronic device with the case protects the electronic device and enables the electronic device to physically connect to a peripheral device to make it available for immediate use, and to prevent it from being misplaced, or lost.

The step 96 selects a peripheral device from a group of peripheral devices enables multiple peripheral devices to be alternatively, or in some cases, simultaneously used.

The step 98 attaches the selected peripheral device to the receiver plate to stow the peripheral device in proximity with the electronic device, and thereby assures that the selected peripheral device is readily available for use.

The step 100 detaches the selected peripheral device from the receiver plate to enable optimal placement of the selected peripheral device in proximity to the electronic device for use.

The step 102 establishes electronic communication between the electronic device and the selected peripheral device via any networking protocol, but preferably current, or to be developed, Bluetooth™ protocols.

The steps 96-102 repeat to enable substation of another peripheral device for the first-selected peripheral device. Options for peripheral devices are not intended to be limited by this disclosure, but do certainly include: a retractable ear-bud mechanism, a speaker, a battery charger, a video projector, a flexible video display screen, a microphone, a printer, a heart rate monitor, pedometer, health testing devices, and a scientific measurement device.

While the present invention is disclosed in terms of various embodiments, including preferred embodiments, it can be appreciated that the true scope of the invention is defined only by the appended claims.

1. A kit of parts for an electronic device, comprising:
a case for an electronic device, the case has a receiver plate attachable to a peripheral device;
a peripheral device attachable to the receiver plate and being capable of electronic communication with the electronic device;
the receiver plate being rigid and defining recesses that are configured to hold a peripheral device;
the peripheral device including feet that align with the recesses to enable the peripheral device to attach to the receiver plate of the case;
wherein the peripheral device is selected from the group consisting of, a retractable ear-bud mechanism, a speaker, a solar battery charger, a video projector, a flexible video display screen.

2. The kit of parts as set forth in claim 1, wherein the receiver plate includes four recesses arranged in a rectangular configuration.

3. The kit of parts as set forth in claim 2, wherein the peripheral device includes four feet that align with the four recesses of the receiver plate when the peripheral device attaches to the receiver plate.

4. The kit of parts as set forth in claim 1, wherein the plate attaches to the case.

5. The kit of parts as set forth in claim 1, wherein the plate is integrated into the case.

6. The kit of parts as set forth in claim 1, wherein the plate includes magnets attached to the plate, the magnets and the recesses cooperate to retain the peripheral device on the plate.

7. The kit of parts as set forth in claim 6, wherein one magnet attaches to the plate adjacent each recess.

8. The kit of parts as set forth in claim 1, wherein the electronic device is a smart phone and peripheral device is a speaker having a Bluetooth interface capable of communicating with the smart phone.

9. The kit of parts as set forth in claim 1, wherein the electronic device is a smart phone and peripheral device is a video projector having a wireless interface capable of networked communication with the smart phone.

10. The kit of parts as set forth in claim 1, wherein the electronic device is a smart phone and the peripheral device is a solar battery charger and a speaker, the solar battery charger being capable of wired electronic communication with the smart phone and with the speaker, the solar battery charger folds for stowage and attachment to the electronic device, and unfolds for capturing light to charge the electronic device.

11. The kit of parts as set forth in claim 1, wherein the electronic device is a smart phone and the peripheral device is a screen, the screen is flexible and rolls from a stowed configuration where the screen is sized for attachment to the electronic device, and an operational configuration where the screen unrolls.

12. The kit of parts as set forth in claim 11, wherein the screen is a roll-up OLED screen.

13. The kit of parts as set forth in claim 11, wherein the screen is a roll-up OLED screen having two ends, and roller tube at each of the two ends that selectively dispense and retract the screen.

14. The kit of parts as set forth in claim 11, wherein the screen is a roll-up OLED screen having two ends, and roller tube at each of the two ends that selectively dispense and retract the screen and the roller tube includes feet to enable attachment to the retainer plate when the roll-up screen is in the stowed configuration.

15. A kit of parts for an electronic device, comprising:
a case for an electronic device, the case has a first receiver plate attachable to a peripheral device;
a clip stand having a second receiver plat attachable to a peripheral device, the clip stand including a spring loaded clip that moves from a locked configuration to an open configuration;
the clip stand has a stand arm that rotatably mounts on the clip stand to selectively maintain the clip stand in the open configuration to enable the clip stand to orient the peripheral device in an upright position;
a peripheral device attachable to the receiver plate and being capable of electronic communication with the electronic device;
the receiver plate being rigid and defining recesses that are configured to hold a peripheral device;
the peripheral device including feet that align with the recesses to enable the peripheral device to attach to the receiver plate of the case;
wherein the peripheral device is selected from the group consisting of, a retractable ear-bud mechanism, a speaker, a solar battery charger, a video projector, a flexible video display screen.

16. The kit of parts as set forth in claim 15, wherein the clip stand arm has a free end, the free end contacts the clip lock to selectively hold the clip stand in open configuration.

17. The kit of parts as set forth in claim 16, wherein the peripheral device includes four feet, the second receiver plate has four recesses, that align with the four recesses of the second receiver plate when the peripheral device attaches to the second receiver plate.

18. The kit of parts as set forth in claim 17, wherein the first receiver plate has four recesses, that align with the four recesses of the first receiver plate when the peripheral device attaches to the first receiver plate,
wherein the recesses of the first receiver plate and the recesses of the second receiver plate are configured to enable selective mounting of the peripheral device to either the first receiver plate or the second receiver plate.

19. The kit of parts as set forth in claim 18, wherein the recesses of the first receiver plate and the recesses of the second receiver plate are the same.

20. A method for using kit of parts for an electronic device, comprising:
providing a case for an electronic device, the case has a receiver plate attachable to a peripheral device;
encasing the electronic device with the case to protect the electronic device and to enable the electronic device to physically connect to a peripheral device;
attaching a peripheral device to the receiver plate to stow the peripheral device in proximity with the electronic device, and thereby assure that the peripheral device is readily available for use;
detaching the peripheral device from the receiver plate to enable optimal placement of the peripheral device in proximity to the electronic device; and
establishing electronic communication between the electronic device and the peripheral device;
wherein the peripheral device is selected from the group consisting of, a retractable ear-bud mechanism, a speaker, a solar battery charger, a video projector, a flexible video display screen.

21. The method of claim 20, wherein the peripheral device is selected from the group consisting of a retractable ear-bud mechanism, and a speaker;
the peripheral device has wireless communication capability for receiving audio signals from the electronic device, and
the method includes communicating audio signals from the electronic device to the peripheral devices.

22. The method of claim 21, wherein the electronic device is a smart phone and establishing electronic communication includes utilizing Bluetooth™ communication protocols.

23. The method of claim 20, wherein the electronic communication between the electronic device and the peripheral device is achieved wirelessly.

24. A method for using kit of parts for an electronic device, comprising:
providing a case for an electronic device, the case has a receiver plate attachable to a peripheral device;
encasing the electronic device with the case to protect the electronic device and to enable the electronic device to physically connect to a peripheral device;
selecting a peripheral device from a group of peripheral devices;
attaching the selected peripheral device to the receiver plate to stow the peripheral device in proximity with the electronic device, and thereby assure that the selected peripheral device is readily available for use;
detaching the selected peripheral device from the receiver plate to enable optimal placement of the selected peripheral device in proximity to the electronic device; and
establishing electronic communication between the electronic device and the selected peripheral device.

25. (canceled)
